(19) United States
(12) Patent Application Publication
(10) Pub. No.: US 2026/0247971 A1
(43) Pub. Date: Aug. 20, 2026

(54) SEMICONDUCTOR PACKAGE

(71) Applicant: Samsung Electronics Co., Ltd., Suwon-si (KR)

(72) Inventor: Hyunsoo Chung, Suwon-si (KR)

(21) Appl. No.: 19/380,478

(22) Filed: Nov. 5, 2025

(30) Foreign Application Priority Data
Feb. 20, 2025 (KR) 10-2025-0022019

(51) Int. Cl. H01L 23/427; H01L 23/00; H01L 23/31; H01L 23/538; H01L 25/18; H10B 80/00; H10D 80/30

(52) U.S. Cl. CPC H10W 40/73; H10B 80/00; H10D 80/30; H10W 70/611; H10W 90/00; H10W 90/401; H10W 72/07354; H10W 72/347; H10W 72/877; H10W 74/121; H10W 74/15; H10W 90/724; H10W 90/734

(57) ABSTRACT

A semiconductor package includes a first substrate including a first redistribution circuit, a second substrate disposed on the first substrate, the second substrate including a second redistribution circuit connected to the first redistribution circuit, a plurality of electronic components disposed on the second substrate, the plurality of electronic components interconnected through the second redistribution circuit, an encapsulation layer disposed on the plurality of electronic components and exposing an upper surface of each of the plurality of electronic components i, and a heat dissipation structure disposed on the encapsulation layer, the heat dissipation structure including a vapor chamber including a lower wall and an upper wall opposite to each other, and a sidewall connecting the lower wall and the upper wall to each other, a plurality of wicks disposed on the lower wall and the upper wall, and a plurality of capillary passages disposed on the sidewall.

### CROSS-REFERENCE TO RELATED APPLICATION(S)

This application claims benefit of an earlier filing date and right of priority under 35 USC § 119 to Korean Patent Application No. 10-2025-0022019 filed on Feb. 20, 2025 in the Korean Intellectual Property Office, the disclosure of which is incorporated herein by reference in its entirety.

### BACKGROUND

With the recent trend toward high-capacity and high-performance electronic devices, semiconductor packages including a plurality of electronic components have been developed. When high-performance electronic components are disposed to be adjacent to each other, it may be difficult to dissipate and transfer heat, and thermal interference may occur between the plurality of electronic components.

### SUMMARY

An aspect of the present disclosure is to provide a semiconductor package.

According to an aspect of the present disclosure, there is provided a semiconductor package including a first substrate including a first redistribution circuit, a second substrate disposed on the first substrate, the second substrate including a second redistribution circuit connected to the first redistribution circuit, a plurality of electronic components disposed on the second substrate, the plurality of electronic components interconnected through the second redistribution circuit, an encapsulation layer disposed on the plurality of electronic components and exposing an upper surface of each of the plurality of electronic components, and a heat dissipation structure disposed on the encapsulation layer, the heat dissipation structure including a vapor chamber including a lower wall and an upper wall opposite to each other, and a sidewall connecting the lower wall and the upper wall to each other, a plurality of wicks disposed on the lower wall and the upper wall, and a plurality of capillary passages disposed on the sidewall.

According to another aspect of the present disclosure, there is provided a semiconductor package including a first substrate, a second substrate disposed on the first substrate, a plurality of electronic components disposed on the second substrate, an encapsulation layer covering at least a portion of each of the plurality of electronic components, a partial adhesive layer surrounding a side surface of each of the plurality of electronic components, on the encapsulation layer, and a heat dissipation structure disposed on the partial adhesive layer, the heat dissipation structure including a vapor chamber overlapping at least one of the plurality of electronic components. The heat dissipation structure may be in contact with an upper surface of each of the plurality of electronic components exposed from the partial adhesive layer, and an upper surface of the partial adhesive layer.

According to another aspect of the present disclosure, there is provided a semiconductor package including a first substrate, a second substrate disposed on the first substrate, a plurality of electronic components disposed on the second substrate, an encapsulation layer covering at least a portion of each of the plurality of electronic components, and a heat dissipation structure disposed on the encapsulation layer, the heat dissipation structure including a first heat dissipation plate, the first heat dissipation plate having a first cavity, a second heat dissipation plate disposed on the first heat dissipation plate, the second heat dissipation plate having a second cavity aligned with the first cavity in a vertical direction, and a vapor chamber defined by the first cavity and the second cavity. The first and second heat dissipation plates may include a semiconductor material.

### BRIEF DESCRIPTION OF DRAWINGS

The above and other aspects, features, and advantages of the present disclosure will be more clearly understood from the following detailed description.

FIG. 1A is a plan view of a semiconductor package according to some example implementations, FIG. 1B is a cross-sectional view taken along line I-I′ of FIG. 1A, and FIG. 1C is a perspective view of a heat dissipation structure according to some example implementations.

FIG. 2A is a plan view of a semiconductor package according to some example implementations, FIG. 2B is a cross-sectional view taken along line II-II′ of FIG. 1A, and FIG. 2C is a perspective view of a heat dissipation structure according to some example implementations.

FIG. 3 is a cross-sectional view of a semiconductor package according to some example implementations.

FIG. 4 is a cross-sectional view of a semiconductor package according to some example implementations.

FIG. 5 is a cross-sectional view of a semiconductor package according to some example implementations.

FIG. 6 is a cross-sectional view of a semiconductor package according to some example implementations.

FIG. 7 is a cross-sectional view of a semiconductor package according to some example implementations.

FIG. 8 is a cross-sectional view of a semiconductor package according to some example implementations.

FIGS. 9A, 9B, 9C, 9D, and 9E are diagrams illustrating a method of manufacturing a heat dissipation structure according to some example implementations.

FIGS. 10A, 10B, 10C, and 10D are diagrams illustrating a method of manufacturing a semiconductor package according to some example implementations.

FIGS. 11A, 11B, and 11C are diagrams illustrating a method of manufacturing a semiconductor package according to some example implementations.

### DETAILED DESCRIPTION

Hereinafter, preferred example implementations will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

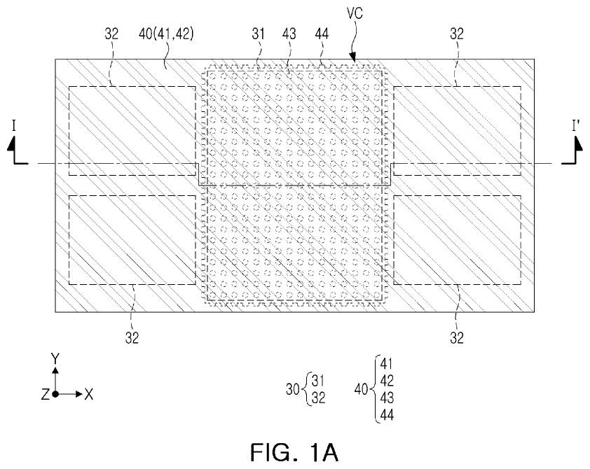

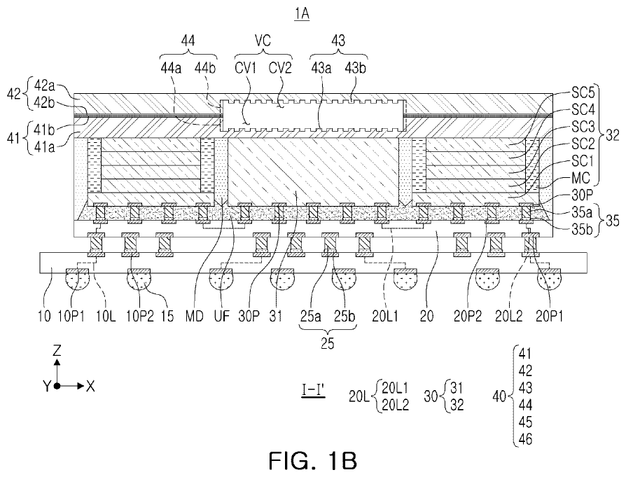

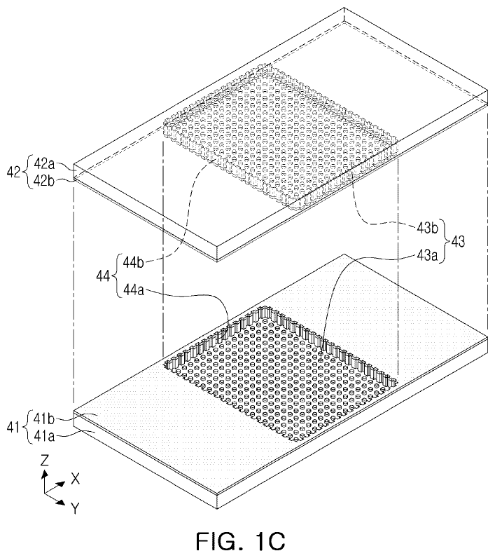

FIG. 1A is a plan view of a semiconductor package 1A according to some example implementations, FIG. 1B is a cross-sectional view taken along line I-I′ of FIG. 1A, and FIG. 1C is a perspective view of a heat dissipation structure 40 according to some example implementations.

Referring to FIGS. 1A to 1C, a semiconductor package 1A according to some example implementations may include a first substrate 10, a second substrate 20, a plurality of electronic components 30, and a heat dissipation structure 40. Depending on example implementations, the semiconductor package 1A may further include an encapsulation layer MD.

The first substrate 10 may be a semiconductor package substrate including a printed circuit board (PCB), a ceramic substrate, a glass substrate, a tape wiring substrate, or the like. The first substrate 10 may include lower pads 10P1, upper pads 10P2, and a first redistribution circuit 10L.

The lower pads 10P1 may be disposed on a lower surface of the first substrate 10, and the upper pads 10P2 may be disposed on an upper surface of the first substrate 10. The lower pads 10P1 and the upper pads 10P2 may be electrically connected to each other through the first redistribution circuit 10L. The lower pads 10P1 and the upper pads 10P2 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). The first redistribution circuit 10L may be formed of a material similar to those of the lower pads 10P1 and the upper pads 10P2.

The upper pads 10P2 may be connected to first bump structures 25 disposed between the second substrate 20 and the first substrate 10. The lower pads 10P1 may be connected to connection bumps 15 disposed below the first substrate 10. The connection bumps 15 may be, for example, solder balls formed of tin (Sn) or an alloy including tin (Sn). In some example implementations, an underfill layer, surrounding the first bump structures 25, may be formed between the first substrate 10 and the second substrate 20.

The second substrate 20 may be an interposer substrate disposed between the first substrate 10 and the electronic components 30. The second substrate 20 may include lower terminals 20P1, upper terminals 20P2, and a second redistribution circuit 20L. The lower terminals 20P1 and the upper terminals 20P2 may be pads positioned to be opposite to each other. The lower terminals 20P1 and the upper terminals 20P2 may include at least one metal or an alloy including at least two metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The second redistribution circuit 20L may include a first circuit 20L1 interconnecting the electronic components 30 through the upper terminals 20P2, and a second circuit 20L2 connecting the lower terminals 20P1 and the upper terminals 20P2 to each other. The upper terminals 20P2 may be connected to second bump structures 35 disposed between the electronic component 30 and the second substrate 20. The lower terminals 20P1 may be connected to the first bump structures 25 disposed below the second substrate 20.

The plurality of electronic components 30 may include a semiconductor wafer and an integrated circuit (IC) including a semiconductor element such as silicon or germanium, or a compound semiconductor such as silicon carbide (SiC), gallium arsenide (GaAs), indium arsenide (InAs), or indium phosphide (InP). The electronic components 30 may be bare semiconductor chips in which no bump or wiring layer is formed, but the present disclosure is not limited thereto, and may be packaged-type semiconductor chips.

The plurality of electronic components 30 may be disposed on the second substrate 20. The electronic components 30 may include connection pads 30P connected to the IC. The connection pads 30P may include at least one metal or an alloy including at least two metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The connection pads 30P may be electrically connected to the upper terminals 20P2 of the second substrate 20 through the second bump structures 35. The plurality of electronic components 30 may be electrically connected to each other through the second redistribution circuit 20L.

The plurality of electronic components 30 may include a logic chip such as a central processing unit (CPU), a graphics processing unit (GPU), a field programmable gate array (FPGA), an application processor (AP), a digital signal processor, an cryptographic processor, a microprocessor, a microprocessor, an analog-to-digital converter, or an application-specific IC (ASIC), or a memory chip including a volatile memory such as dynamic RAM (DRAM) or static RAM (SRAM), and a nonvolatile memory such as phase change RAM (PRAM), magnetic RAM (RRAM), or flash memory.

The plurality of electronic components 30 may include a first electronic component 31 and a second electronic component 32 including different types of semiconductor chips. For example, the first electronic component 31 may include a logic chip such as a CPU, a GPU, an FPGA, a digital signal processor, a cryptographic processor, a microprocessor, an analog-to-digital converter, or an ASIC, and the second electronic component 32 may include a memory chip such as DRAM, SRAM, PRAM, ReRAM, FeRAM, MRAM, or flash memory. Depending on example implementations, the second electronic component 32 may be provided as a high-performance memory device such as high bandwidth memory (HBM) or hybrid memory tube (HMC). The second electronic component 32 may include a plurality of semiconductor chips SC1, SC2, SC3, SC4, and SC5 and a mold layer MC. The number of the plurality of semiconductor chips SC1, SC2, SC3, SC4, and SC5 may be greater or less than that illustrated in the drawings. The plurality of semiconductor chips SC1, SC2, SC3, SC4, and SC5 may be stacked in a vertical direction (Z-direction) using a thermo-compression bonding method or a hybrid bonding method. The plurality of semiconductor chips SC1, SC2, SC3, SC4, and SC5 may be interconnected through a through-silicon via (TSV). The plurality of semiconductor chips SC1, SC2, SC3, SC4, and SC5 may include a buffer chip SC1 and a plurality of memory chips (for example, SC2, SC3, SC4, and SC5). For example, the mold layer MC may include an insulating material such as an epoxy molding compound (EMC).

The first and second bump structures 25 and 35 may electrically connect the first substrate 10, the second substrate 20, and the electronic components 30 to each other. The first and second bump structures 25 and 35 may include filler bumps 25a and 35a and solder balls 25b and 35b, respectively. The filler bumps 25a and 35a may be in contact with a lower terminal 20P1 of the second substrate 20 or a connection pad 30P of the electronic component 30. The filler bumps 25a and 35a may include at least one metal or an alloy including at least two metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The filler bumps 25a and 35a may each have a cylindrical or polygonal pillar shape. The solder balls 25b and 35b may each be in contact with an upper pad 10P2 of the first substrate 10 or an upper terminal 20P2 of the second substrate 20. The solder balls 25b and 35b may each be formed of tin (Sn) or an alloy including tin (Sn), for example, an alloy including at least two metals, among tin (Sn), lead (Pb), silver (Ag), copper (Cu), and bismuth (Bi). Depending on example implementations, at least one of the first and second bump structures 25 and 35 may include only one of the filler bumps 25a and 35a and the solder balls 25b and 35b.

The encapsulation layer MD may be disposed on the plurality of electronic components 30 and exposing an upper surface of each of the plurality of electronic components 30. The heat dissipation structure 40 (or a “first heat dissipation plate 41”) may be in contact with and be coupled to the upper surface of each of the plurality of electronic components 30 exposed from the encapsulation layer MD. The encapsulation layer MD may be formed on the second substrate 20 in a wafer level packaging process, and an external surface of the encapsulation layer MD may be coplanar with an external surface of the heat dissipation structure 40 and an external surface of the second substrate 20. The encapsulation layer MD may include an insulating material such as a thermosetting resin such as an epoxy resin, a thermoplastic resin such as polyimide, or a resin, for example, a prepreg, an Ajinomoto build-up film (ABF), frame retardant-4 (FR-4), bismaleimide-triazine (BT), or an EMC in which the thermosetting resin or the thermoplastic resin is impregnated with an inorganic filler. Depending on example implementations, the semiconductor package 1A may further include an underfill layer UF surrounding the second bump structures 35. The underfill layer UF may be formed to encapsulate the second bump structures 35 using a capillary underfill (CUF) method. In some example implementations, the underfill layer UF may be formed integrally with the encapsulation layer MD using a mole underfill (MUF) method.

The heat dissipation structure 40 may be disposed on the encapsulation layer MD and the plurality of electronic components 30. The heat dissipation structure 40 may include a vapor chamber VC overlapping an electronic component in at least one of the plurality of electronic components 30. The vapor chamber VC may be formed to have a position and a size overlapping an electronic component generating a relatively large amount of heat. For example, when the first electronic component 31 has a hot spot at a higher temperature compared to the second electronic component 30, the vapor chamber VC may be formed at a position overlapping the first electronic component 31. In plan view, the first electronic component 31 may be positioned inside of the vapor chamber VC, and the second electronic component 32 may be positioned outside of the vapor chamber VC. The second electronic component 32 may have a second planar area, less than a first planar area of the first electronic component 31, and the vapor chamber VC may have a planar area equal to or greater than the first planar area. In some example implementations, the vapor chamber VC may have a planar area greater than that of the first electronic component 31, and may overlap at least a portion of the second electronic component 32. In some example implementations, a heat dissipation plate may be disposed on an upper portion of the heat dissipation structure 40.

The vapor chamber VC may be configured to dissipate and disperse heat from the hot spot using vaporization and condensation of a refrigerant. For example, the vapor chamber VC may be defined by a lower wall and an upper wall opposite to each other, and a sidewall connecting the lower wall and the upper wall to each other, and a small amount of refrigerant may be injected into the vapor chamber VC. The heat dissipation structure 40 may include a plurality of wicks 43 and a plurality of capillary passages 44, formed in the vapor chamber VC. The vapor chamber VC according some example implementations may be formed to have a thermal conductivity of about 20,000 W/mK or more. The vapor chamber VC may have a thermal conductivity higher than that of each of bodies 41a and 42a of the heat dissipation structure 40, such that the hot spot of the first electronic component 31 may be rapidly removed, and heat generated in the first electronic component 31 may be discharged in the vertical direction (Z-direction), thereby preventing thermal interference with the second electronic component 32.

The plurality of wicks 43 may be disposed on the lower wall and the upper wall of the vapor chamber VC. The plurality of wicks 43 may be configured to move a liquid refrigerant to a heat source through a capillary action and to accelerate evaporation of the liquid refrigerant by increasing a surface area. A diameter, height, and spacing of the plurality of wicks 43 may be determined based on a size of the vapor chamber VC and a type of refrigerant.

The plurality of capillary passages 44 may be disposed on the sidewall of the vapor chamber VC. The plurality of capillary passages 44 may extend from the lower wall to the upper wall along the sidewall of the vapor chamber VC. The plurality of capillary passages 44 may be configured to separate a gaseous refrigerant and the liquid refrigerant from each other, and to provide a path through which the liquid refrigerant flows. A length, depth, and width of the plurality of capillary passages 44 may be determined based on a size of the vapor chamber VC and a type of refrigerant.

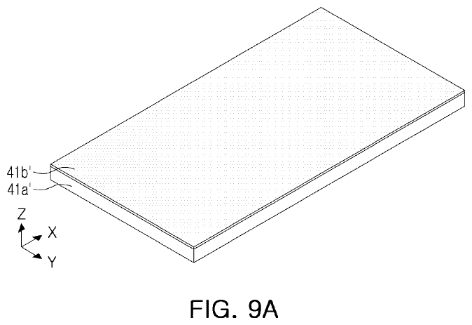

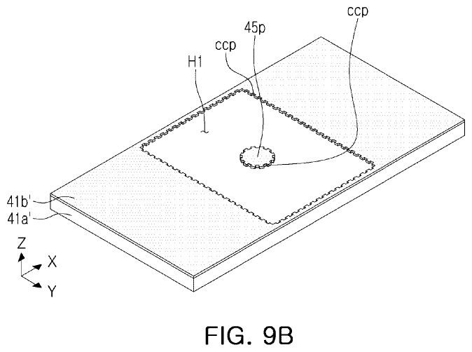

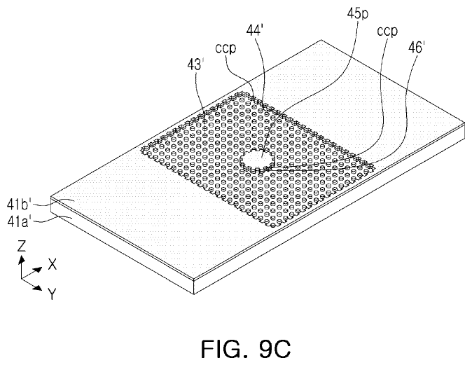

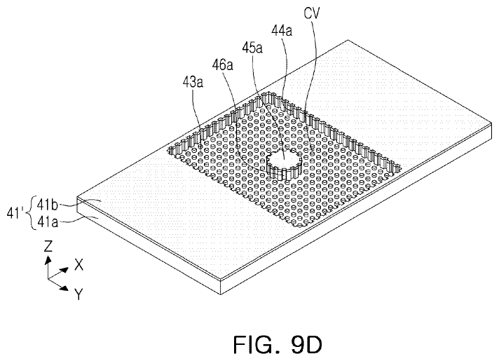

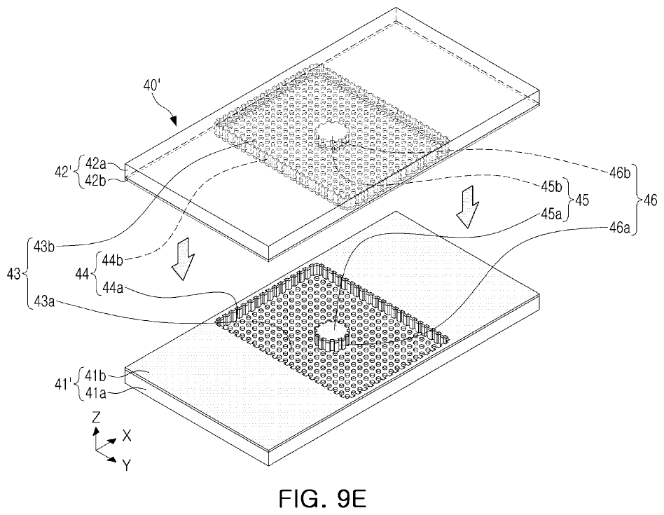

In some example implementations, the heat dissipation structure 40 may include a pair of heat dissipation plates 41 and 42 including a semiconductor material. The above-described vapor chamber VC, the plurality of wicks 43, and the plurality of capillary passages 44 may be formed by locally etching the pair of heat dissipation plates 41 and 42 (for example, bulk silicon). A method of manufacturing the heat dissipation structure 40 will be described in detail with reference to FIGS. 9A to 9E. The heat dissipation structure 40 may include a first heat dissipation plate 41 and a second heat dissipation plate 42.

The first heat dissipation plate 41 may be disposed on the electronic components 30 and the encapsulation layer MD, and may include a first body 41a and a first bonding layer 41b on the first body 41a. The first body 41a may include a semiconductor material (for example, silicon (Si), and the first bonding layer 41b may include a material (for example, silicon oxide (SiO) having an etch selectivity with respect to the first body 41a. The first heat dissipation plate 41 may have a first cavity CV1 for forming the vapor chamber VC. The first cavity CV1 may be defined by the lower wall and a first inner wall. The first cavity CV1 may pass through the first bonding layer 41b and extend to the inside of the first body 41a. The first heat dissipation plate 41 may include first wicks 43a disposed on the lower wall and first capillary passages 44a disposed on the first inner wall.

The second heat dissipation plate 42 is disposed on the first heat dissipation plate 41, and may include a second body 42a and a second bonding layer 42b under the second body 42a. The second body 42a may include a semiconductor material (for example, silicon (Si) and the second bonding layer 42b may include a material (for example, silicon oxide (SiO) having an etch selectivity with respect to the second body 42a. The second bonding layer 42b may be in direct contact with the first bonding layer 41b. The first heat dissipation plate 41 and the second heat dissipation plate 42 may be in close contact with each other by dielectric-dielectric bonding between the first bonding layer 41b and the second bonding layer 42b. The second heat dissipation plate 42 may have a second cavity CV2 for forming the vapor chamber VC. The second cavity CV2 may be defined by an upper wall and a second inner wall. The second cavity CV2 may penetrate the second bonding layer 42b and extend inside the second body 42a. The second cavity CV2 may be aligned with the first cavity CV1 in the vertical direction (Z-direction). The second heat dissipation plate 42 may include second wicks 43b disposed on an upper wall and second capillary passages 44b disposed on a second inner wall. The vapor chamber VC may be formed by the first cavity CV1 and the second cavity CV2. The first capillary passages 44a and the second capillary passages 44b may be connected to each other to form capillary passages 44 on the sidewall of the vapor chamber VC.

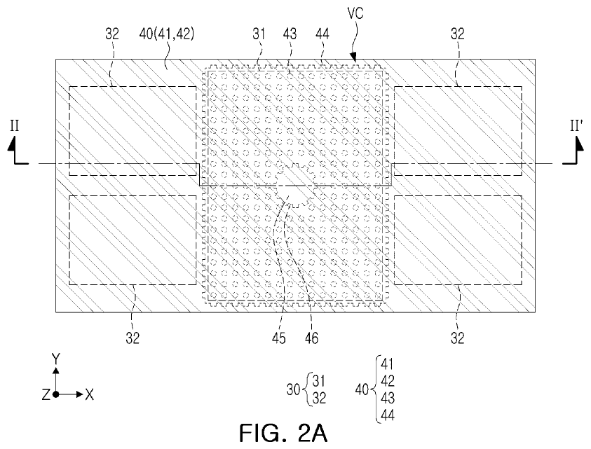

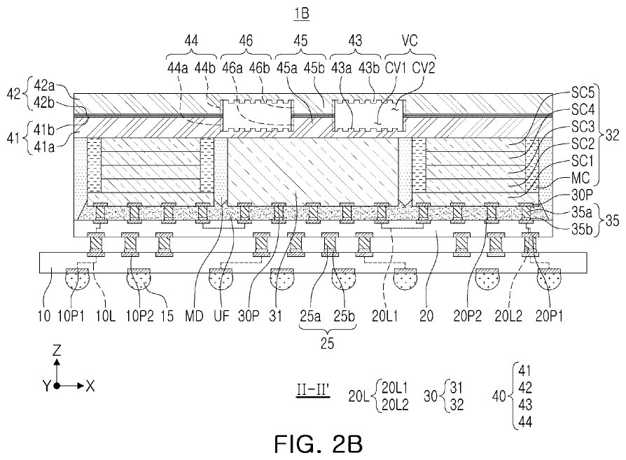

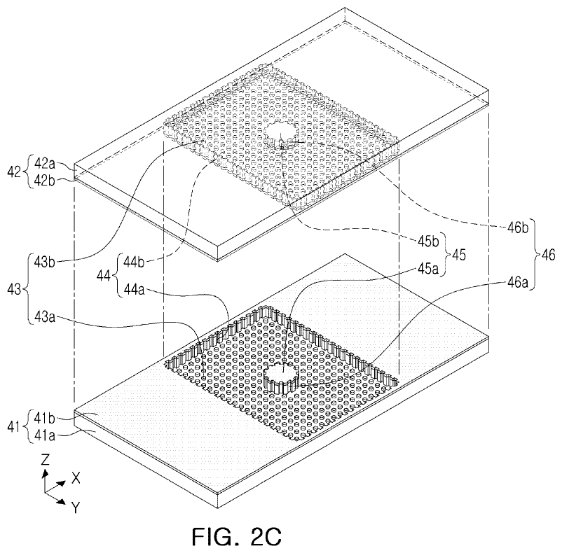

FIG. 2A is a plan view of a semiconductor package 1B according to some example implementations, FIG. 2B is a cross-sectional view taken along line II-II′ of FIG. 1A, and FIG. 2C is a perspective view of a heat dissipation structure 40 according to some example implementations.

Referring to FIGS. 2A to 2C, the semiconductor package 1B according to some example implementations may have features same as or similar to those described with reference to FIGS. 1A to 1C, except that the semiconductor package 1B further includes a support pillar 45 in a vapor chamber VC. The heat dissipation structure 40 may further include the support pillar 45 disposed in the vapor chamber VC. The support pillar 45 may support an upper wall and a lower wall of the vapor chamber VC. In addition, the heat dissipation structure 40 may further include an additional capillary passage 46 disposed on an outer peripheral surface of the support pillar 45. The additional capillary passage 46 may extend from the lower wall to the upper wall of the vapor chamber VC along the outer peripheral surface of the support pillar 45. The support pillar 45 may include a first pillar 45a extending from the lower wall of the vapor chamber VC, and a second pillar 45b extending from the upper wall of the vapor chamber VC. The first pillar 45a may be a portion of each of a first body 41a and a first bonding layer 41b. The second pillar 45b may be a portion of each of a second body 42a and a second bonding layer 42b. The first pillar 45a and the second pillar 45b may be in close contact with each other and bonded to each other through dielectric bonding of the first bonding layer 41b and the second bonding layer 42b. The additional capillary passage 46 may include a first additional capillary passage 46a formed on an outer peripheral surface of the first pillar 45a, and a second additional capillary passage 46b formed on an outer peripheral surface of the second pillar 45b. The first additional capillary passage 46a and the second additional capillary passage 46b may be connected to each other to form additional capillary passages 46 on the outer peripheral surface of the support pillar 45.

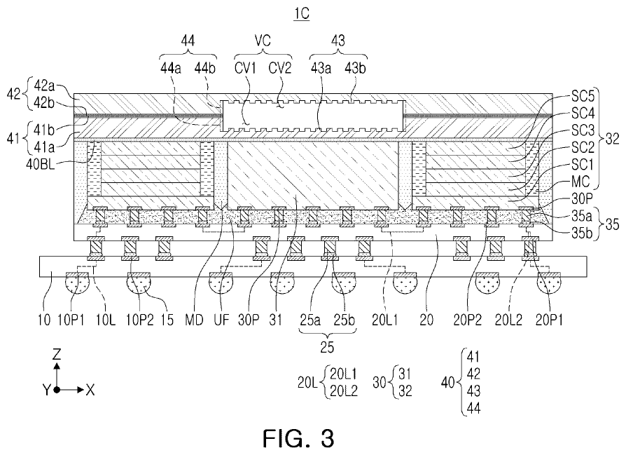

FIG. 3 is a cross-sectional view of a semiconductor package 1C according to some example implementations.

Referring to FIG. 3, the semiconductor package 1C according to some example implementations may have features same as or similar to those described with reference to FIGS. 1A to 2C, except that a heat dissipation structure 40 further includes an adhesive layer 40BL. The adhesive layer 40BL may be disposed below the heat dissipation structure 40. The adhesive layer 40BL may be formed on a lower surface of a first heat dissipation plate 41 to improve adhesion between the heat dissipation structure 40 and electronic components 30. The adhesive layer 40BL may be in contact with an upper surface of each of a plurality of electronic components 30 and an encapsulation layer MD. The upper surface of each of the plurality of electronic components 30 and an upper surface of the encapsulation layer MD may be coplanar with each other. The adhesive layer 40BL may include a material having excellent adhesion to the upper surfaces of the electronic components 30, for example, silicon oxide (SiO), but the present disclosure is not limited thereto. In some example implementations, the adhesive layer 40BL may include a thermal interface material (TIM) such as a thermally conductive adhesive tape, a thermally conductive grease, a thermally conductive adhesive, or the like. The adhesive layer 40BL may improve adhesion of the heat dissipation structure 40 and improve heat dissipation efficiency.

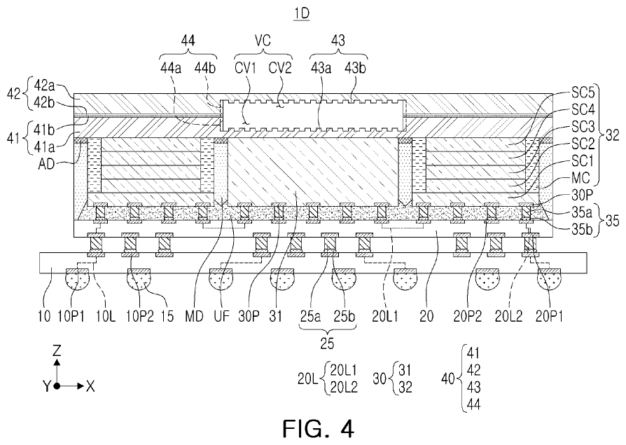

FIG. 4 is a cross-sectional view of a semiconductor package 1D according to some example implementations.

Referring to FIG. 4, the semiconductor package 1D according to some example implementations may have features the same as or similar to those described with reference to FIGS. 1A to 3, except that the semiconductor package 1D further includes a partial adhesive layer AD between a heat dissipation structure 40 and an encapsulation layer MD. The partial adhesive layer AD may be disposed on an upper surface of the encapsulation layer MD having a step portion with respect to upper surfaces of electronic components 30. The partial adhesive layer AD may be disposed between the heat dissipation structure 40 and the encapsulation layer MD, spaced apart from each other. The partial adhesive layer AD may be formed to surround a side surface of each of a plurality of electronic components 30. An external surface of the heat dissipation structure 40, an external surface of the partial adhesive layer AD, and an external surface of the encapsulation layer MD may be coplanar with each other. An upper surface of the partial adhesive layer AD may be coplanar with an upper surface of each of the plurality of electronic components 30. The partial adhesive layer AD may be in direct contact with the heat dissipation structure 40. The heat dissipation structure 40 may be in contact with the upper surface of each of the plurality of electronic components 30 exposed from the partial adhesive layer AD, and the upper surface of the partial adhesive layer AD. At least a portion of each of the plurality of electronic components 30, providing the upper surface of each of the plurality of electronic components 30, may include a semiconductor material (for example, silicon (Si), and at least a portion of the partial adhesive layer AD, providing the upper surface of the partial adhesive layer AD, may include a TIM. The partial adhesive layer AD may improve adhesion of the heat dissipation structure 40, and improve heat dissipation efficiency.

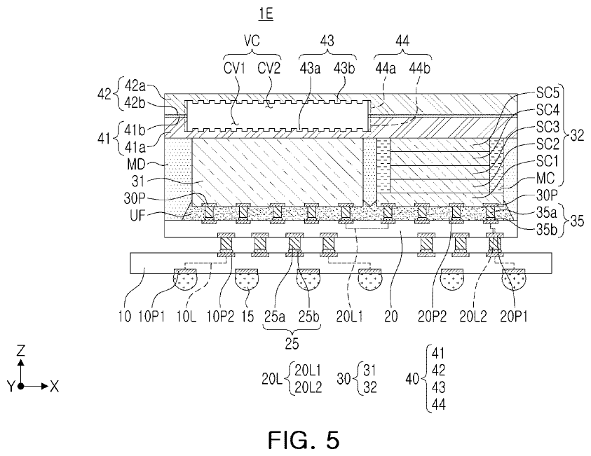

FIG. 5 is a cross-sectional view of a semiconductor package 1E according to some example implementations.

Referring to FIG. 5, the semiconductor package 1E according to some example implementations may have features the same as or similar to those described with reference to FIGS. 1A to 4, except that the semiconductor package 1E includes a vapor chamber VC asymmetrically disposed in a heat dissipation structure 40. The vapor chamber VC may be positioned to overlap an electronic component, generating a larger amount of heat, among a plurality of electronic components 30. For example, the plurality of electronic components 30 may include a first electronic component 31 adjacent to a first side of a second substrate 20, and a second electronic component 32 adjacent to a second side of the second substrate 20. When the first electronic component 31 includes a logic chip such as a CPU or a GPU, and the second electronic component 32 includes a memory chip, the vapor chamber VC may be formed in the heat dissipation structure 40 at a position corresponding to a position of the first electronic component 31.

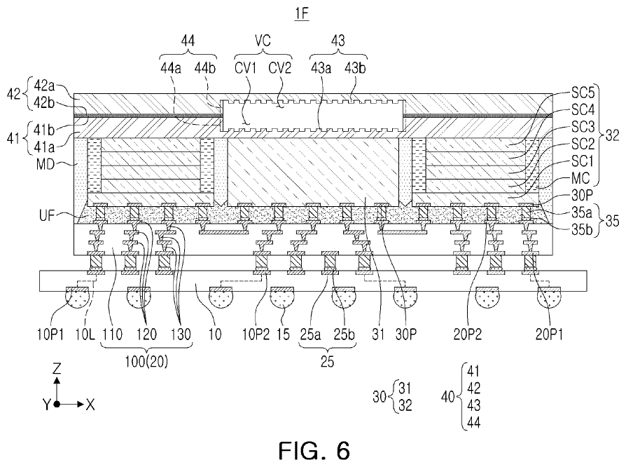

FIG. 6 is a cross-sectional view of a semiconductor package 1F according to some example implementations.

Referring to FIG. 6, the semiconductor package 1F according to some example implementations may have features the same as or similar to those described with reference to FIGS. 1A to 5, except that the semiconductor package 1F includes a first type of interposer substrate 100. The interposer substrate 100 may be understood to correspond to the second substrate 20 described with reference to FIG. 1A and the like.

The interposer substrate 100 may include an insulating layer 110, a redistribution layer 120, and a redistribution via 130. The insulating layer 110 may include an insulating resin. The insulating resin may include a thermosetting resin such as an epoxy resin, a thermoplastic resin such as polyimide, or a resin, for example, a prepreg, an ABF, FR-4, BT, or an EMC, in which the thermosetting resin or the thermoplastic resin is impregnated with an inorganic filler. In some example implementations, the insulating layer 110 may include a photosensitive resin such as a photoimageable dielectric (PID). The insulating layer 110 may include a plurality of insulating layers stacked in a vertical direction (Z-direction). Depending on a process thereof, the plurality of insulating layers may have unclear boundaries therebetween.

The redistribution layer 120 may be disposed on and in the insulating layer 110, and may redistribute connection pads 30P of an electronic component 30. The redistribution layer 120 may include, for example, a metal including copper (Cu), aluminum (Al), silver (Ag), tin (Sn), gold (Au), nickel (Ni), lead (Pb), titanium (Ti), or alloys thereof. The redistribution layer 120 may perform various functions depending on a design thereof. For example, the redistribution layer 120 may include a ground pattern, a power pattern, and a signal pattern. Here, the signal pattern may be defined as a transmission path of various signals, for example, a data signal and the like, excluding a ground pattern, a power pattern, and the like. The number of the redistribution layers 120 may be greater than or less than the number of those illustrated in the drawings.

The redistribution via 130 may extend from the inside of the insulating layer 110 to be electrically connected to the redistribution layer 120. For example, the redistribution via 130 may interconnect the redistribution layers 120 having different levels. The redistribution via 130 may include, for example, a metal material including copper (Cu), aluminum (Al), silver (Ag), tin (Sn), gold (Au), nickel (Ni), lead (Pb), titanium (Ti), or alloys thereof. The redistribution via 130 may be a filled via in which a metal material is filled in a via hole or a conformal via in which a metal material extends along an inner wall of a via hole.

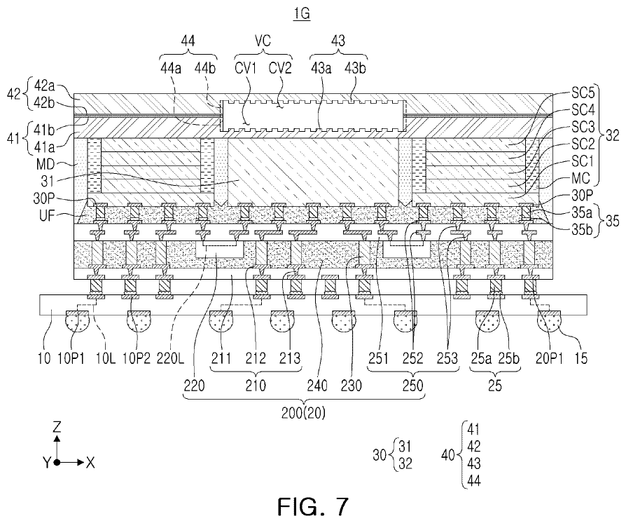

FIG. 7 is a cross-sectional view of a semiconductor package 1G according to some example implementations.

Referring to FIG. 7, the semiconductor package 1G according to some example implementations may have features the same as or similar to those described with reference to FIGS. 1A to 6, except that the semiconductor package 1G includes a second type of interposer substrate 200. The interposer substrate 200 may be understood to correspond to the second substrate 20 described with reference to FIG. 1A and the like. The interposer substrate 200 may include an interconnection chip 220 configured to electrically connect the electronic components 30 to each other. For example, the interposer substrate 200 may include a lower redistribution structure 210, an interconnection chip 220, through-vias 230, a mold 240, and an upper redistribution structure 250.

The lower redistribution structure 210 may include an insulating layer 211, a redistribution layer 212, and a redistribution via 213. The insulating layer 211 may be formed using a photosensitive resin. For example, the insulating layer 211 may include a polyimide (PI)-based photosensitive polymer, a polybenzoxazole (PBO)-based photosensitive polymer, a polyhydroxystyrene (PHS)-based photosensitive polymer, a novolak-based photosensitive polymer, a benzocyclobutene (BCB)-based photosensitive polymer, or a PID.

The redistribution layer 212 may be disposed on or in the insulating layer 211, and may be electrically connected to the interconnection chip 220, the through-vias 230, and electronic components 30. The redistribution layer 212 may include, for example, copper (Cu), aluminum (Al), silver (Ag), tin (Sn), gold (Au), nickel (Ni), lead (Pb), titanium (Ti), or alloys thereof. The redistribution layer 212 may include a ground pattern, a power pattern, and a signal pattern depending on a design thereof. The signal pattern may provide a transmission path of various signals (for example, a data signal), excluding the ground pattern, the power pattern, and the like. The redistribution layer 212 may include various types of conductive lines extending in a horizontal direction X and/or Y.

The redistribution via 213 may pass through the insulating layer 211 to be electrically connected to the redistribution layer 212. The redistribution via 213 may have a side surface that is tapered toward the first substrate 10. The redistribution via 213 may include, for example, copper (Cu), aluminum (Al), silver (Ag), tin (Sn), gold (Au), nickel (Ni), lead (Pb), titanium (Ti), or alloys thereof. The redistribution via 213 may be a filled via in which a metal material is filled in a via hole or a conformal via in which a metal material extends along an inner wall of a via hole.

The interconnection chip 220 may be disposed on the lower redistribution structure 210. The interconnection chip 220 may include an interconnection circuit 220L for electrically connecting the first electronic component 31 and the second electronic component 32 to each other. The interconnection chip 220 may be a semiconductor chip in which the interconnection circuit 220L is formed on a semiconductor substrate, but the present disclosure is not limited thereto.

The through-vias 230 may be disposed around the interconnection chip 220, and may be electrically connected to the redistribution layer 212. The through-vias 230 may be in the form of a post extending in a vertical direction (Z-direction) to correspond to a thickness of the interconnection chip 220. A surface (for example, an upper surface) of each of the through-vias 230 may be coplanar with a surface (for example, an upper surface) of the mold 240 by a planarization process. The through-vias 230 may include copper (Cu), aluminum (Al), silver (Ag), tin (Sn), gold (Au), nickel (Ni), lead (Pb), titanium (Ti), or alloys thereof.

The mold 240 may be disposed between the lower redistribution structure 210 and the upper redistribution structure 250. The mold 240 may be formed to encapsulate the interconnection chip 220 and the through-vias 230. The mold 240 may include, for example, a thermosetting resin such as an epoxy resin, a thermoplastic resin such as polyimide, or a prepreg, ABF, FR-4, BT, or an EMC in which the thermosetting resin or the thermoplastic resin is impregnated with an inorganic filler.

The upper redistribution structure 250 may include an upper insulation layer 251, an upper redistribution layer 252, and an upper redistribution via 253. The upper insulation layer 251, the upper redistribution layer 252, and the upper redistribution via 253 may have features substantially similar to those of the insulating layer 211, the redistribution layer 212, and the redistribution via 213 described above, respectively, and thus, a repeated description thereof will be omitted. The upper redistribution layer 252 may be connected to the interconnection circuit 220L through the upper redistribution via 253. The electronic components 30 may be electrically connected to the interconnection chip 220 through the upper redistribution layer 252.

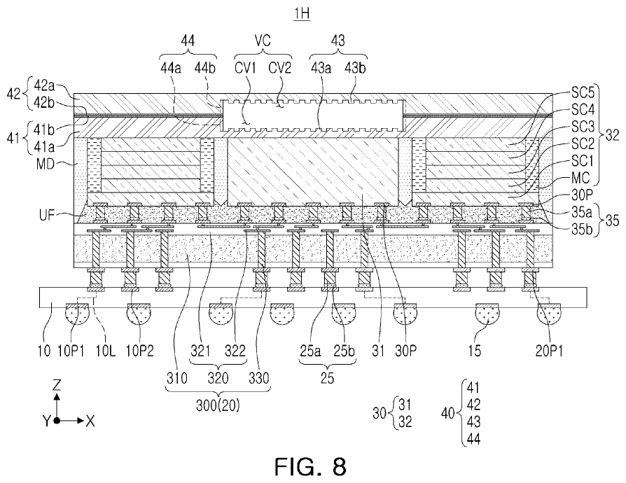

FIG. 8 is a cross-sectional view of a semiconductor package 1H according to some example implementations.

Referring to FIG. 8, the semiconductor package 1H according to some example implementations may have features the same as or similar to those described with reference to FIGS. 1A to 7, except that the semiconductor package 1H includes a third type of interposer substrate 300. The interposer substrate 300 may be understood to correspond to the second substrate 20 described with reference to FIG. 1A and the like.

The interposer substrate 300 may include a substrate 310, an interconnection structure 320, and a through-electrode 330. The electronic components 30 may be electrically connected to each other through the interposer substrate 300.

The substrate 310 may be formed as, for example, one of silicon, organic, plastic, and glass substrates. When the substrate 310 is a silicon substrate, the interposer substrate 300 may be referred to as a silicon interposer. An insulating film, surrounding lower portions of the through-electrodes 330, may be formed between the substrate 310 and lower terminals 20P1.

The interconnection structure 320 may be disposed on the substrate 310, and may include an interlayer insulating layer 321 and a single-layer or multilayer wiring structure 322. When the interconnection structure 320 has a multilayer wiring structure, wiring patterns of different layers may be connected to each other through a contact via.

The through-electrode 330 may pass through the substrate 310 to electrically connect the lower terminals 20P1 and upper terminals 20P2 to each other. When the substrate 310 is a silicon substrate, the through-electrode 330 may be referred to as a TSV.

In some example implementations, the interposer substrate 300 may be used to convert or transmit an input electrical signal between electronic components 30. The interposer substrate 300 may not include devices such as an active device or a passive device.

FIGS. 9A to 9E are diagrams illustrating a method of manufacturing a heat dissipation structure 40 according to some example implementations. FIGS. 9A to 9E schematically illustrate a manufacturing process of the heat dissipation structure 40 illustrated in FIGS. 2A to 2C.

Referring to FIG. 9A, a preliminary bonding layer 41b′ may be formed on a body layer 41a′. The body layer 41a′ may be bulk silicon (for example, a silicon wafer) including a plurality of unit regions illustrated in the drawings. The preliminary bonding layer 41b′ may include a material (for example, silicon oxide) having an etch selectivity with respect to the body layer 41a′. The preliminary bonding layer 41b′ may be conformally formed on a surface of the body layer 41a′. The preliminary bonding layer 41b′ may be formed using a physical vapor deposition (PVD) process or a chemical vapor deposition (CVD) process.

Referring to FIG. 9B, an etching region H1, passing through the preliminary bonding layer 41b′, may be formed. The etching region H1 may be formed by partially removing the preliminary bonding layer 41b′ using a photolithography process, an etching process, or the like. Depending on example implementations, a preliminary pillar region 45p may be formed in the etching region H1. The preliminary pillar region 45p may be a portion of the preliminary bonding layer 41b′ remaining in the etching region H1. The etching region H1 may be formed to have a concave-convex pattern ccp at an edge thereof. The concave-convex pattern ccp may be formed along a periphery of the etching region H1 and a periphery of the preliminary pillar region 45p.

Referring to FIG. 9C, a preliminary wick 43′ and a preliminary capillary passage 44′ may be formed on the body layer 41a′. The preliminary wick 43′ and the preliminary capillary passage 44′ may be formed by partially removing the body layer 41a′ using a photolithography process, an etching process, or the like. The preliminary wick 43′ may be formed using a patterned photosensitive material (for example, photoresist (PR)) as an etching mask. The preliminary capillary passage 44′ may be formed using a patterned photosensitive material (for example, PR) or the preliminary bonding layer 41b′ as an etching mask. The preliminary capillary passage 44′ may be aligned with the concave-convex pattern ccp, formed along the periphery of the etching region H1 and the periphery of the preliminary pillar region 45p, in a vertical direction (Z-direction).

Referring to FIG. 9D, a preliminary heat dissipation plate 41′ including a cavity CV, a plurality of wicks 43a, and a plurality of capillary passages 44a may be formed. The cavity CV may be formed by etching the body layer 41a′ using the preliminary bonding layer 41b′ as a mask. The cavity CV may be formed using an anisotropic etching process such as a reactive ion etching (RIE). The cavity CV may be defined by a lower wall on which the plurality of wicks 43a are formed, and an inner wall on which the plurality of capillary passages 44a are formed.

Referring to FIG. 9E, a preliminary heat dissipation structure 40′ may be formed by coupling a first preliminary heat dissipation plate 41′ and a second preliminary heat dissipation plate 42′ to each other. Each of the first preliminary heat dissipation plate 41′ and the second preliminary heat dissipation plate 42′ may be bulk silicon (for example, a silicon wafer) formed through the above-described process. The first preliminary heat dissipation plate 41′ may include first wicks 43a disposed on a lower wall, and first capillary passages 44a disposed on a first inner wall. The second preliminary heat dissipation plate 42′ may include second wicks 43b disposed on an upper wall, and second capillary passages 44b disposed on a second inner wall. The first preliminary heat dissipation plate 41′ and the second preliminary heat dissipation plate 42′ may be in close contact with each other and bonded to each other by dielectric-dielectric bonding between the first bonding layer 41b and the second bonding layer 42b. The first bonding layer 41b and the second bonding layer 42b may be performed in a thermal atmosphere in a range of about 100° C. to 300° C. However, the temperature of the thermal atmosphere is not limited to the above-described range, and may be changed in various manners. The first capillary passages 44a and the second capillary passages 44b may be connected to each other to form capillary passages 44 on a sidewall of a vapor chamber VC.

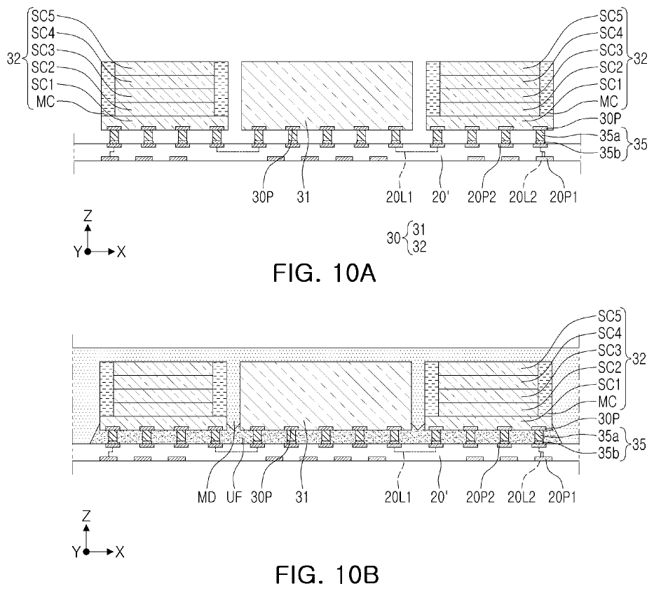

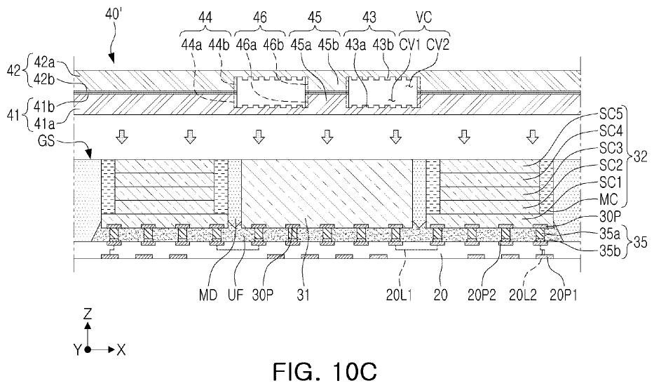

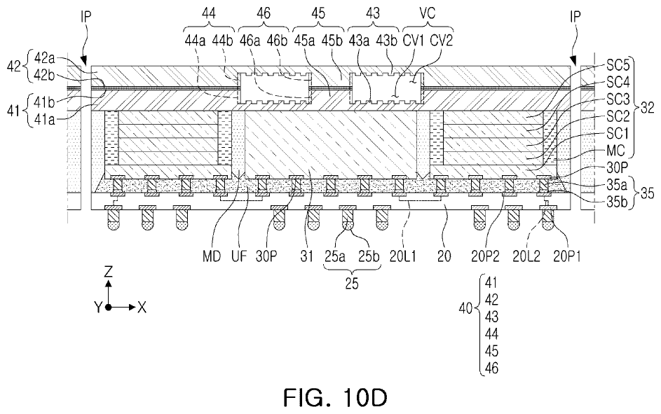

FIGS. 10A to 10D are diagrams illustrating a method of manufacturing a semiconductor package according to some example implementations. FIGS. 10A to 10D schematically illustrate a manufacturing process of the semiconductor package 1B illustrated in FIGS. 2A to 2C.

Referring to FIG. 10A, a plurality of electronic components 30 may be mounted on a preliminary substrate 20′. The preliminary substrate 20′ may be a wafer substrate including a plurality of unit substrates. The plurality of electronic components 30 may be connected to redistribution circuits 20L1 and 20L2 of the preliminary substrate 20′ through a bump structure 35.

Referring to FIG. 10B, an encapsulation layer MD, disposed on the plurality of electronic components 30, may be formed. The encapsulation layer MD may be formed by coating and curing an encapsulation material (for example, an EMC) on the preliminary substrate 20′. Depending on example implementations, an underfill layer UF may be formed between the electronic components 30 and the preliminary substrate 20′. Thereafter, a planarization process may be applied to the encapsulation layer MD, such that a planarization surface, to which an upper surface of each of the plurality of electronic components 30 is exposed, may be formed.

Referring to FIG. 10C, a preliminary heat dissipation structure 40′ may be attached to the planarization surface GS to which the upper surface of each of the plurality of electronic components 30 is exposed. The preliminary heat dissipation structure 40′ may be a bulk silicon (for example, silicon wafer) structure corresponding to a planar shape and size of the preliminary substrate 20′. The preliminary heat dissipation structure 40′ may be directly bonded to the upper surface of each of the plurality of electronic components 30 exposed to the planarization surface GS in a thermal atmosphere.

Referring to FIG. 10D, an interposer package IP to which the heat dissipation structure 40 is attached may be separated using a sawing process. The preliminary substrate 20′, the encapsulation layer MD, and the preliminary heat dissipation structure 40′ may be cut together to form, such that an external surface of the heat dissipation structure 40, an external surface of the encapsulation layer MD, and an external surface of the substrate 20 may be coplanar with each other. As described above, the heat dissipation structure 40 may be configured to efficiently remove a hot spot formed in a first electronic component 31. Accordingly, the interposer package IP may have improved heat dissipation properties and reliability. Thereafter, a semiconductor package according to some example implementations may be formed by mounting the interposer package IP on the package substrate 10′ in FIG. 2B.

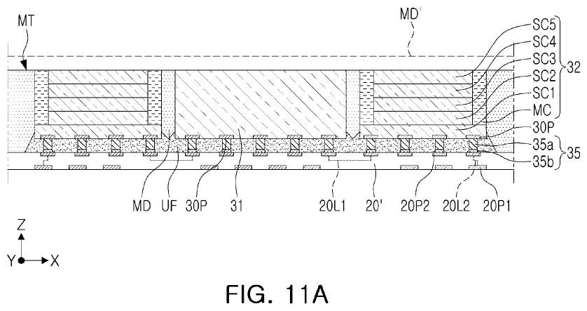

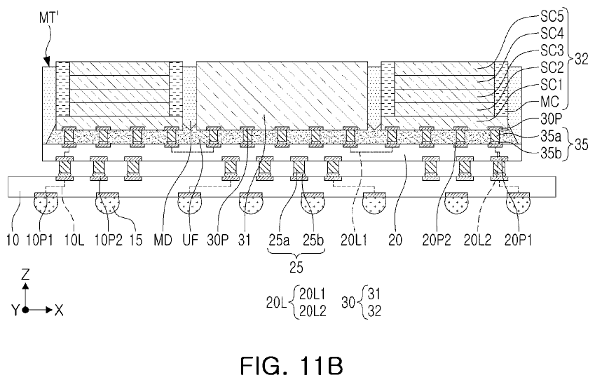

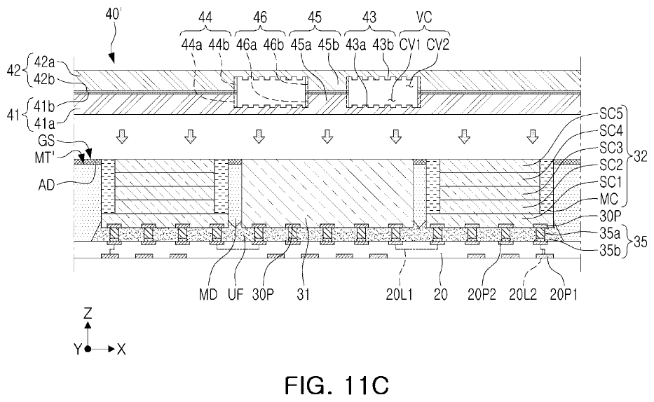

FIGS. 11A to 11C are diagrams illustrating a method of manufacturing a semiconductor package according to some example implementations. FIGS. 11A to 11C schematically illustrate a process of manufacturing a semiconductor package in which the example embodiment of FIGS. 2A to 2C and the example embodiment of FIG. 4 are combined with each other.

Referring to FIG. 11A, an upper region MD′ of the encapsulation layer MD may be removed. An upper surface MT of the encapsulation layer MD may be coplanar with upper surfaces of electronic components 30. The upper region MD′ of the encapsulation layer MD may be removed using a planarization process such as a grinding process or the like.

Referring to FIG. 11B, the encapsulation layer MD may be additionally etched. The encapsulation layer MD may be additionally etched using an etching mask or using an etching selectivity between the electronic components 30 and the encapsulation layer MD. An upper surface MT′ of the additionally etched encapsulation layer MD may be positioned on a level, lower than that of the upper surface of each of the electronic components 30.

Referring to FIG. 11C, a partial adhesive layer AD may be formed on the upper surface MT′ of the additionally etched encapsulation layer MD. The partial adhesive layer AD may be formed using a TIM. The partial adhesive layer AD may be formed to surround a side surface of each of the plurality of electronic components 30 exposed from the additionally etched encapsulation layer MD. An upper surface of the partial adhesive layer AD may be coplanar with an upper surface of each of the plurality of electronic components 30. The upper surface of the partial adhesive layer AD may form a planarization surface GS to which the upper surface of each of the plurality of electronic components 30 is exposed. Thereafter, an interposer package including the partial adhesive layer AD may be formed by performing the processes in FIGS. 10C and 10D.

According to another aspect of the present disclosure, there is provided method of manufacturing a semiconductor package, the method including mounting a plurality of electronic components on a preliminary substrate, forming an encapsulation layer disposed on the plurality of electronic components, forming a planarization surface to which an upper surface of each of the plurality of electronic components are exposed, attaching a preliminary heat dissipation structure to the planarization surface, cutting the preliminary substrate and the preliminary heat dissipation structure to form an interposer package, and mounting the interposer package on a package substrate. The preliminary heat dissipation structure may include a plurality of wicks disposed on a lower wall and an upper wall of a vapor chamber, and a plurality of capillary passages disposed on a sidewall of the vapor chamber.

A method of manufacturing the preliminary heat dissipation structure may include forming a preliminary bonding layer on a body layer, forming an etching region passing through the preliminary bonding layer, the preliminary bonding layer including a concave-convex pattern formed along an edge of the etching region, forming a preliminary wick and a preliminary capillary passage on the body layer, the preliminary capillary passage being aligned with the concave-convex pattern in a vertical direction, anisotropically etching the body layer to form a cavity, the cavity being defined by a lower wall on which a plurality of wicks are formed and an inner wall on which a plurality of capillary passages are formed, and coupling a pair of preliminary heat dissipation plates that each include a respective cavity to each other. The pair of preliminary heat dissipation plates may include a first preliminary heat dissipation plate having a first cavity, and a second preliminary heat dissipation plate having a second cavity. The preliminary heat dissipation structure in which the pair of preliminary heat dissipation plates are coupled to each other may include a vapor chamber defined by the first cavity and the second cavity.

According to example implementations of the present disclosure, a heat dissipation structure having improved heat dissipation efficiency may be introduced, thereby providing a semiconductor package having improved reliability.

While example implementations have been shown and described above, it will be apparent to those skilled in the art that modifications and variations could be made without departing from the scope of the present disclosure as defined by the appended claims.

What is claimed is:

1. A semiconductor package comprising:
a first substrate including a first redistribution circuit;
a second substrate disposed on the first substrate, the second substrate including a second redistribution circuit connected to the first redistribution circuit;
a plurality of electronic components disposed on the second substrate, the plurality of electronic components interconnected through the second redistribution circuit;
an encapsulation layer disposed on the plurality of electronic components and exposing an upper surface of each of the plurality of electronic components; and
a heat dissipation structure disposed on the encapsulation layer, the heat dissipation structure including:
a vapor chamber including a lower wall, an upper wall, and a sidewall connecting the lower wall with the upper wall,
a plurality of wicks disposed on the lower wall and the upper wall, and
a plurality of capillary passages disposed on the sidewall.

2. The semiconductor package of claim 1, wherein the plurality of capillary passages extend between the lower wall and the upper wall along the sidewall of the vapor chamber.

3. The semiconductor package of claim 1, wherein the heat dissipation structure includes:
a first heat dissipation plate having a first cavity defined by the lower wall and a first inner wall; and
a second heat dissipation plate disposed on the first heat dissipation plate, the second heat dissipation plate having a second cavity aligned with the first cavity in a vertical direction, the second cavity defined by the upper wall and a second inner wall, and
wherein the vapor chamber is defined by the first cavity and the second cavity.

4. The semiconductor package of claim 3, wherein the first heat dissipation plate includes a first body and a first bonding layer on the first body,
wherein the second heat dissipation plate includes a second body and a second bonding layer below the second body, and
wherein the first bonding layer and the second bonding layer are in contact with each other.

5. The semiconductor package of claim 4, wherein the first body and the second body include silicon (Si), and
wherein the first bonding layer and the second bonding layer include silicon oxide (SiO).

6. The semiconductor package of claim 1, wherein the heat dissipation structure includes a support pillar disposed in the vapor chamber.

7. The semiconductor package of claim 6, wherein the heat dissipation structure includes an additional capillary passage extending between the lower wall and the upper wall along an outer peripheral surface of the support pillar.

8. The semiconductor package of claim 1, wherein the heat dissipation structure is in contact with the upper surface of each of the plurality of electronic components.

9. The semiconductor package of claim 8, wherein the heat dissipation structure includes an adhesive layer in contact with the upper surface of each of the plurality of electronic components and the encapsulation layer.

10. The semiconductor package of claim 9, wherein the adhesive layer includes silicon oxide (SiO).

11. The semiconductor package of claim 8, wherein the heat dissipation structure is spaced apart from the encapsulation layer, and
wherein the semiconductor package includes a partial adhesive layer disposed between the encapsulation layer and the heat dissipation structure.

12. The semiconductor package of claim 11, wherein the partial adhesive layer includes a thermal interface material (TIM).

13. The semiconductor package of claim 1, wherein the plurality of electronic components include a first electronic component and a second electronic component, and
wherein the first electronic component is positioned inside of the vapor chamber, and the second electronic component is positioned outside of the vapor chamber.

14. The semiconductor package of claim 13, wherein the first electronic component has a first planar area,
wherein the second electronic component has a second planar area, the second planar area being less than the first planar area, and
wherein the vapor chamber has a planar area, the planar area being equal to or greater than the first planar area.

15. The semiconductor package of claim 13, wherein the first electronic component includes a logic chip, and
wherein the second electronic component includes a memory chip.

16. A semiconductor package comprising:
a first substrate;
a second substrate disposed on the first substrate;
a plurality of electronic components disposed on the second substrate;
an encapsulation layer disposed on the plurality of electronic components;
a partial adhesive layer surrounding a side surface of each of the plurality of electronic components, on the encapsulation layer; and
a heat dissipation structure disposed on the partial adhesive layer, the heat dissipation structure including a vapor chamber overlapping at least one of the plurality of electronic components,
wherein the heat dissipation structure is in contact with an upper surface of each of the plurality of electronic components exposed from the partial adhesive layer, and is in contact with an upper surface of the partial adhesive layer.

17. The semiconductor package of claim 16, wherein
at least a portion of each of the plurality of electronic components provides the upper surface of each of the plurality of electronic components and includes a semiconductor material, and
at least a portion of the partial adhesive layer provides the upper surface of the partial adhesive layer and includes a TIM.

18. The semiconductor package of claim 16, wherein the upper surface of each of the plurality of electronic components and the upper surface of the partial adhesive layer are coplanar with each other.

19. The semiconductor package of claim 16, wherein an external surface of the heat dissipation structure, an external surface of the partial adhesive layer, and an external surface of the encapsulation layer are coplanar with each other.

20. A semiconductor package comprising:
a first substrate;
a second substrate disposed on the first substrate;
a plurality of electronic components disposed on the second substrate;
an encapsulation layer disposed on the plurality of electronic components; and
a heat dissipation structure disposed on the encapsulation layer, the heat dissipation structure including a first heat dissipation plate having a first cavity, a second heat dissipation plate disposed on the first heat dissipation plate and having a second cavity aligned with the first cavity in a vertical direction, and a vapor chamber defined by the first cavity and the second cavity,
wherein the first and second heat dissipation plates include a semiconductor material.
